(19) United States
(12) Patent Application Publication
(10) Pub. No.: US 2002/0109970 A1
(43) Pub. Date: Aug. 15, 2002

(54) Heat sink for cooling electronic chip

(75) Inventors: Si Young Yang, Suwon-Shi (KR); Hyung Hwan Jun, Suwon-Shi (KR); Jae Woong Kwon, Seoul (KR); Se Min Oh, Suwon-Shi (KR)

Correspondence Address: DARBY & DARBY P.C., 805 Third Avenue, New York, NY, 10022, US

(73) Assignee: SAMSUNG ELECTRO-MECHANICS CO., LTD., SUWON-SHI (KR)

(21) Appl. No.: 09/812,798

(22) Filed: Mar. 20, 2001

(30) Foreign Application Priority Data
Dec. 18, 2000 (KR) 2000-78040

(51) Int. Cl. H05K 7/20

(52) U.S. Cl. 361/695

(57) ABSTRACT

Disclosed is a heat sink for discharging an electronic chip, including a body contacting the surface of the electronic chip at one major surface thereof and received heat emitted from the surface of the electronic chip, the one major surface of the body being flat; a plurality of heat discharge fins formed integrally with the body and adapted to discharge the heat, transferred to the body, to the atmosphere, the heat discharge fins being protruded from the other major surface of the body while being uniformed spaced from one another; and a plurality of corrugated louver fin members each interposed between adjacent ones of the heat discharge fins and formed by repeatedly bending a thin plate member to have a wave shape, each of the corrugated louver fin members having a plurality of louvers adapted to create a turbulent flow of air while varying the direction of the air flow. In accordance with the heat sink, it is possible to obtain a maximum heat conduction cross-sectional area and a maximum convective heat transfer area, thereby achieving a great improvement in heat discharge characteristics.

### BACKGROUND OF THE INVENTION

1. Field of the Invention

The present invention relates to a heat sink for providing heat discharge characteristics for an electronic chip, such as an integrated circuit package, from which a large quantity of heat is generated. In particular, the present invention relates to a heat sink for cooling an electronic chip, which can improve a thermal conduction from the electronic chip and provide a maximized convective thermal transfer area, thereby providing an improved cooling performance.

2. Description of the Related Art

Electronic chips, such as central processing units (CPUs) of computers, which have recently been developed to achieve an ultra miniature, a high processing speed, and a high capacity, involve an increase in the quantity of heat generated therefrom. Due to the miniature and high density made in electronic products, simultaneously with an improvement in performance, however, the conditions for removing heat generated have been rendered to be more severe.

The quantity of heat generated from integrated circuit packages (hereinafter, those integrated circuit packages are referred to as CPUs) has been continuously increased in proportion to the increase in the performance of computers. For instance, although heat of 8 W or less is generated from CPUs of a 486 grade, for example, 66 MHz, developed at the past, heat of 16 to 35 W is typically generated from CPUs of a 1,000 MHz grade. In the case of CPUs of a GHz grade, it is expected that heat of 50 W or more is generated.

Meanwhile, the current tendency associated with computers is to reduce the size. This tendency causes the thermal conditions of CPUs to be severe. For this reason, it is important to effectively discharge heat generated from CPUs in order to obtain a desired reliability and performance in the case of products having a high capacity.

In particular, CPUs involve a problem of hot spots because they are under a high temperature condition, as compared to other elements.

That is, the condition, in which CPUs are heated to a high temperature, results in a degradation in clock speed, an erroneous operation, and an great increase in the error generation rate. It has been reported that an increase in the error generation rate up to 5.2 times occurs when the temperature of a CPU increases by 50° C.

For this reason, active research has been made to develop means for effectively discharging heat generated from a CPU mounted to a computer, in pace with research of CPUs with a high density. For such means for discharging heat generated from a CPU, a cooling device has been developed which includes a heat sink and a heat discharge fan.

In such a cooling device, which includes a heat sink and a heat discharge fan, the heat sink is typically made of a material exhibiting a superior thermal conductivity. In particular, the heat sink has a heat discharge structure for rapidly discharging heat transferred from an electronic chip thereto.

The heat discharge fan is arranged at one side of the heat sink, and has a structure capable of improving the heat discharge characteristics of the heat sink.

FIG. 1 is a perspective view illustrating a conventional pin-drawn type heat sink. FIG. 2 is a side view illustrating a mounted state of the conventional heat sink.

As shown in FIGS. 1 and 2, the conventional heat sink, which is denoted by the reference numeral 100, includes a body 110 closely contacting the heat emitting surface of an electronic chip 200, and a plurality of heat discharge fins 120 adapted to discharge heat transferred to the body 110 into the atmosphere.

The body 110 has a flat lower surface closely contacting the upper surface of the electronic chip 200 via a bonding silicon or other support.

The body 110 is made of an aluminum material exhibiting a superior thermal conductivity so that it effectively receives heat generated from the electronic chip 200.

The heat discharge fins 120 are arranged on the upper surface of the body 110 in such a fashion that they are uniformly spaced from one another while extending vertically from the upper surface of the body 110. The heat discharge fins 120 serve to rapidly discharge heat transferred to the body 110 into the atmosphere in accordance with a convection.

The heat discharge fins 120 are made of an aluminum material exhibiting superior heat discharge characteristics, as in the case of the body 110. The shape, size, and thickness of each heat discharge fin 120 are determined, taking into consideration the heat emitting characteristics of the electronic chip 200.

Where such heat discharge fins 120 are used in an electronic chip 200 generating a small quantity of heat, they conduct a heat discharge function in accordance with a natural convection. On the other hand, where the heat discharge fins 120 are used in an electronic chip 200 generating a large quantity of heat, a fan motor having an air blowing function is provided to conduct a heat discharge function according to a forced convection.

In FIGS. 1 and 2, the reference numeral 300 denotes a printed circuit board on which the electronic chip 200 is mounted.

However, the above mentioned conventional heat sink 100, which is adapted to cool an electronic chip, has a drawback in that it exhibits a degraded cooling performance because the heat transferred thereto is simply discharged in accordance with the convection function of the heat discharge fins 120.

Although it is possible to obtain an enhanced cooling performance of such a heat sink 100 by enlarging the heat transfer surface area and the heat conduction cross-sectional area, this method involves another problem in that the heat sink 100 cannot be mounted on an electronic product configured to have a slim and thin structure because it has an increased size.

Thus, the conventional heat sink 100 exhibits a limitation in the cooling performance for discharging heat in accordance with a convection. For this reason, there is a problem in that it is impossible to efficiently discharge a large quantity of heat generated from electronic chips to be developed in the future to have a high capacity.

That is, an instable operation occurs due to the fact that heat generated from electronic chips configured to generate a large quantity of heat cannot be rapidly discharged. As a result, there is a degradation in the reliability of products.

### SUMMARY OF THE INVENTION

Therefore, an object of the invention is to provide a heat sink for cooling an electronic chip, which includes corrugated louver fins capable of providing a maximum heat transfer surface area and a maximum heat conduction cross-sectional area, thereby achieving an enhancement in the heat discharge performance according to a convection.

In accordance with the present invention, this object is accomplished by providing a heat sink for discharging an electronic chip, comprising: a body closely contacting the surface of the electronic chip at one major surface thereof and received heat emitted from the surface of the electronic chip, the one major surface of the body being flat; a plurality of heat discharge fins formed integrally with the body and adapted to discharge the heat, transferred to the body, to the atmosphere, the heat discharge fins being protruded from the other major surface of the body while being uniformed spaced from one another; and a plurality of corrugated louver fin members each interposed between adjacent ones of the heat discharge fins and formed by repeatedly bending a thin plate member to have a wave shape, each of the corrugated louver fin members having a plurality of louvers adapted to create a turbulent flow of air while varying the direction of the air flow.

The heat sink has a feature in that each of the heat discharge fins has a thickness of 1.0 to 5.0 mm, and the body has a thickness of 2.0 to 10.0 mm.

The heat sink has another feature in that each of the corrugated louver fin members is arranged in parallel to the direction of the air flow and welded to associated ones of the heat discharge fins in accordance with a brazing method, to generate a minimum resistance of the air flow.

The heat sink has another feature in that it further comprises a flow guide space defined between the other major surface of the body and an end of an associated one of the corrugated louver fin members facing the other major surface of the body, the flow guide space having a shape selected from the group consisting of a semi-circular shape, a rectangular shape, and a triangular shape, and a hydraulic diameter of 2.0 to 15.0 mm, and a plurality of fins having various protruded from a portion of the other major surface of the body defined within the flow guide space.

The heat sink has another feature in that each of the corrugated louver fin members is made of an aluminum material coated with a clad material.

The heat sink has another feature in that it further comprises a pair of hooks protruded from those of the heat discharge fins respectively arranged at opposite lateral edges of the body, each of the hooks having a desired height, and a fan motor engaged with the hooks so that it is mounted to the body, the fan motor serving to forcibly blow air toward the heat discharge fins and the corrugated louver fin members.

The heat sink has another feature in that each of the corrugated louver fin members has a thickness of 0.1 to 0.5 mm, a shape bent in the form of corrugated fins having a pitch of 1.0 to 5.0 mm to obtain a maximum heat transfer area, and is provided with louvers formed by cutting each of the corrugated fins to form a plurality of uniformly spaced slits, and then bending portions of the corrugated louver fin defined by the slits, respectively, each of the louvers having an angle of 10 to 50°.

The heat sink has another feature in that the body, the heat discharge fins, and the corrugated louver fin members are made of aluminum or copper.

### BRIEF DESCRIPTION OF THE DRAWINGS

The above objects, and other features and advantages of the present invention will become more apparent after a reading of the following detailed description when taken in conjunction with the drawings, in which:

FIG. 1 is a perspective view illustrating a conventional pin-drawn type heat sink;

FIG. 2 is a side view illustrating a mounted state of the conventional heat sink;

FIG. 3 is a perspective view illustrating a heat sink for cooling an electronic chip in accordance with the present invention;

FIG. 4 is a perspective view illustrating a corrugated louver fin member included in the heat sink according to the present invention;

FIG. 5 is a side view illustrating the corrugated louver fin member according to the present invention;

FIG. 6 is a cross-sectional view taken along the line A-A of FIG. 4;

FIG. 7 is a side view illustrating the heat sink according to the present invention; and

FIG. 8 is a graph depicting the performance of the heat sink according to the present invention.

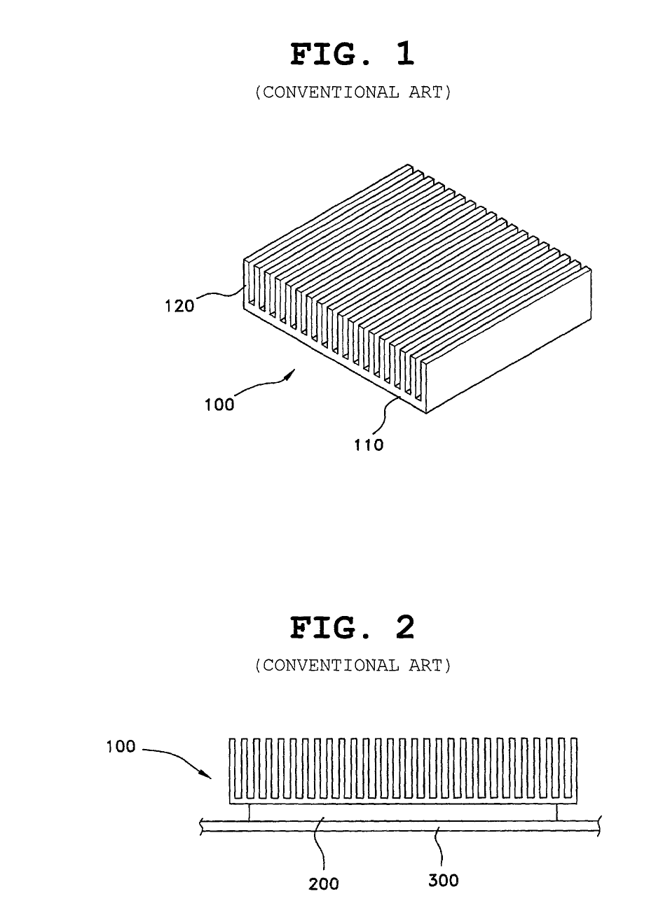

### DESCRIPTION OF THE PREFERRED EMBODIMENTS

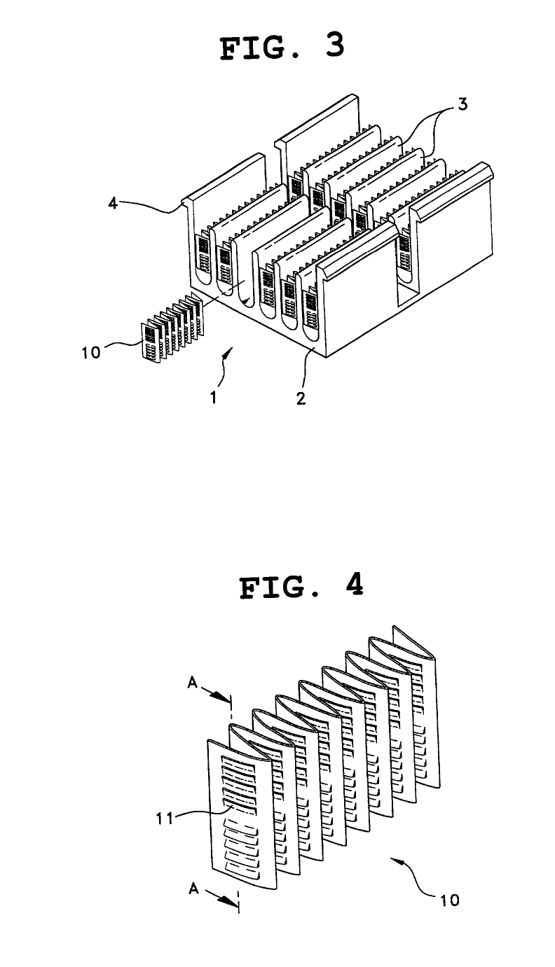

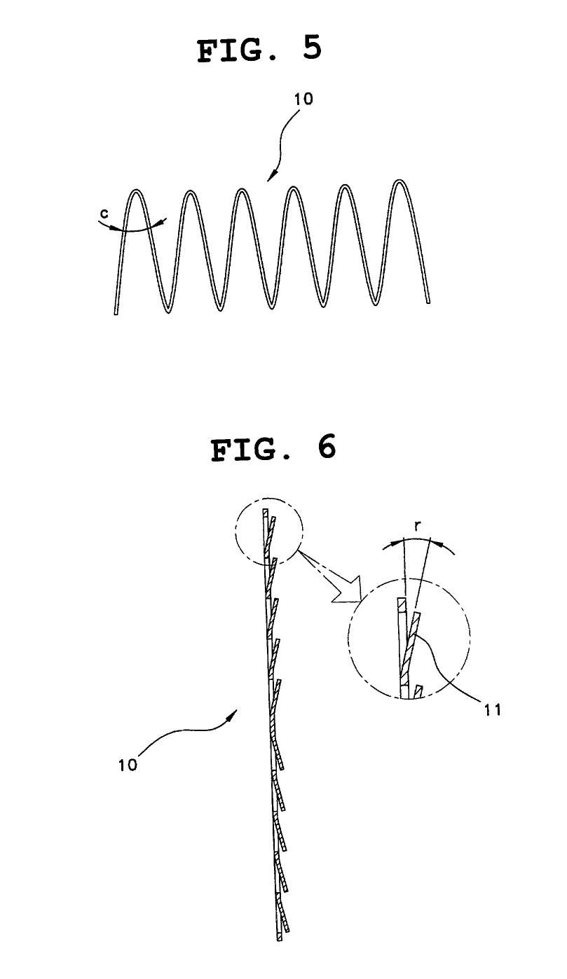

FIG. 3 is a perspective view illustrating a heat sink for cooling an electronic chip in accordance with the present invention. FIG. 4 is a perspective view illustrating a corrugated louver fin member included in the heat sink according to the present invention. In addition, FIG. 5 is a side view illustrating the corrugated louver fin member according to the present invention.

As shown in FIGS. 3 to 5, an integrated circuit package such as a central processing unit (CPU), that is, an electronic chip 6, is mounted on a printed circuit board 7. A heat sink 1, which has a configuration according to the present invention, is provided at a heat emitting surface of the electronic chip 6 in order to ensure desired heat characteristics.

The heat sink 1 mainly includes a body 2, and heat discharge fins 3. The body 2 and heat discharge fins 3 are formed to be integral together in accordance with an extrusion or drawing process. Typically, the body 2 and heat discharge fins 3 are made of aluminum (AA3003 series) or copper.

The body 2 generally has a rectangular shape. As shown in FIGS. 3 to 5, the body 2 has a lower surface machined to be flat. In accordance with the present invention, the body 2 preferably has a thickness of about 2.0 to 10.0 mm.

The flat lower surface of the body 2 is in close contact with the upper surface of the electronic chip 6, that is, a heat emitting surface, so that the body 2 receives heat generated from the electronic chip 6.

The heat discharge fins 3 are integrally formed with the upper portion of the body 2, and upwardly protruded from the body 2 by a desired height while being uniformly spaced apart from one another.

The heat discharge fins 3 are made to have a thickness of 1.0 to 5.0 mm, and adapted to discharge the heat of the electronic chip 6 transferred to the body 2 in accordance with a convection.

Respective thicknesses and shapes of the heat discharge fins 3 and body 2 may be diverse in so far as those heat discharge fins and body have structures capable of receiving heat from the electronic chip 6 and discharging the heat in accordance with a convection.

The above mentioned configuration is substantially similar to that of the conventional heat sink.

The heat sink 1 of the present invention has a feature in that it includes corrugated louver fin members 10 capable of providing a maximum heat transfer surface area and a maximum heat conduction cross-sectional area, thereby achieving an enhancement in heat discharge performance.

As shown in FIG. 4, the corrugated louver fin members 10 are interposed between adjacent ones of the heat discharge fins 3 extending upwardly from the upper surface of the body 2 while being uniformly spaced from one another, respectively. Each corrugated louver fin member 10 is a thin plate member having a superior thermal conductivity. Each corrugated louver fin member 10 is bent to have a wave shape, that is, a corrugated shape, to have a plurality of uniformly spaced louver fins. Each corrugated louver fin member 10 is provided at each louver fin thereof with a plurality of louvers 11 adapted to create a turbulent flow of air while preventing the formation of a thermal boundary layer at the surface of the corrugated louver fin member 10.

Preferably, each corrugated louver fin member 10 is a plate member made of an aluminum material of AA3003 series or a copper material and coated with a clad material. The plate member is bent to have a corrugated shape in order to obtain a maximum heat transfer area.

Preferably, the pitch of the louver fins in each corrugated louver fin member 10 is 1.0 to 5.0 mm. The pitch is denoted by the reference character c in FIG. 5. Preferably, the corrugated louver fin member 10 has a thickness of 0.1 to 0.5 mm.

Where the corrugated louver fin member 10 is configured to have a small thickness while having a minimum pitch within the limits of the possibility so that their louver fins are densely arranged, it is possible to obtain a maximum heat transfer surface area in a limited space, thereby achieving an improvement in heat discharge characteristics.

The louvers 11 serve to promote the creation of turbulent air flows while preventing the formation of a thermal boundary layer at the surface of the associated corrugated louver fin member 10, thereby maximizing heat transfer effects.

The louvers 11 are formed by cutting the associated corrugated louver fin to form a plurality of uniformly spaced slits, and then bending portions of the corrugated louver fin defined by those slits while forming slots, respectively. Preferably, the angle of each louver 11 is 10 to 50°. In FIG. 6, the louver angle is denoted by the reference character r.

Since each corrugated louver fin member 10 is interposed between adjacent heat discharge fins 3, as mentioned above, it is possible to obtain an enhanced heat discharge performance according to a convection.

In order to generate a minimum resistance of air flows, each corrugated louver fin member 10 is arranged in parallel to the air flows. Also, each corrugated louver fin member 10 is welded to the associated heat discharge fins 3 while being arranged in a space defined between those heat discharge fins 3, using a brazing method, in order to generate a minimum thermal resistance in cooperation with the heat discharge fins 3.

The corrugated louver fin members 10 can be manufactured in mass production, using a fin mill mounted with fin rolls adapted to machine a plate member to have a fin shape.

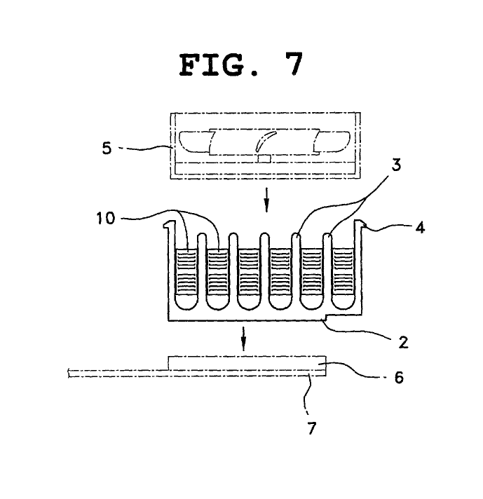

Although the electronic chip-cooling heat sink 1 having the above mentioned configuration may be used as it is, it is preferable that a fan motor 5 is mounted on the heat sink 1, as shown in FIG. 7.

The fan motor 5 may be fixedly mounted, using diverse mounting constructions. In the illustrated case, the heat discharge fins 2 respectively arranged at the opposite lateral edges of the heat sink 1 extend upwardly over the remaining heat discharge fins 2 arranged therebetween, so that they have extensions, respective. A pair of hooks 4 are formed at respective ends of the extensions. Using the hooks 4, the fan motor 5 is mounted on the upper end of the heat sink 1 in an engaged fashion.

When the fan motor 5 arranged over the heat discharge fins 3 is supplied with electric power, blades fitted around a rotating body included in the fan motor 5 rotate, thereby conducting an air blowing function. Thus, a desired quantity of air is blown toward the heat discharge fins 3 and corrugated louver fin members 10 by the fan motor 5, so that the heat discharge characteristics of the heat sink 1 is enhanced.

In order to allow the heat sink to have optimum heat discharge characteristics, it is necessary to optimize the shape and dimension of the heat sink. To this end, it is necessary to design a heat sink having a flow resistance meeting an increase in the pressure of a fan generating an air flow, in order to allow the heat sink to match with the fan.

The flow resistance of the electronic chip-cooling heat sink proposed by the present invention has a feature in that it is expressed by the following experimental equations relating to the frictional coefficient depending on the air velocity.

$$\begin{matrix}f = 5.47 {Re}_{lp}^{- 0.72} {{L}_{n}^{0.37} ( \frac{{L}_{1}}{H} )}^{0.89} {L}_{p}^{0.2} {H}^{0.23} & ( 70 < {Re}_{lp} < 900 ) \\ f = 0.494 {{Re}_{lp}^{- 0.39} ( \frac{{L}_{h}}{H} )}^{0.33} {( \frac{{L}_{1}}{H} )}^{1.1} {H}^{0.46} & ( 1000 < {Re}_{lp} < 4000 )\end{matrix}$$

where, “Reₗₚ” represents the Reynolds number of an air flow having a representative length corresponding to the pitch Lₚ of the louver

$$( {Re}_{lp} = \frac{ρ {VL}_{p}}{1000 μ} ) ,$$

“Lₕ”, “Lₗ”, “Lₚ”, “H”, and “ ”represent the height, length and pitch of the louver, the height of the fin member, and the viscosity coefficient of air, respectively. Respective units of the above mentioned length scales are millimeter.

Accordingly, the flow resistance, dPₐ, generated at the heat sink can be expressed by the following equation:

$${dP}_{a} = f \frac{l}{D} \frac{ρ {V}^{2}}{2}$$

where, “l”, “D”, “ρ”, and “V” represent the width of a tube, a hydraulic diameter, the air density, and the velocity of air passing between adjacent louver fins, respectively.

Also, it is necessary to determine optimum shape and dimension of the electronic chip-cooling heat sink, taking into consideration the quantity of heat generated from the electronic chip.

To this end, it is required to design the heat sink to have a quantity of air meeting the performance of the fan generating an air flow in order to match the heat sink with the fan. In the case of the electronic chip-cooling heat sink proposed by the present invention, the convective heat transfer coefficient, h, having a close relation with the heat discharge performance, Q, can be expressed by the following experimental equation:

$$h = 0.249 ( ρ {VC}_{p} ) {Re}_{lp}^{- 042} {{L}_{h}^{0.33} ( \frac{{L}_{l}}{H} )}^{1.1} {H}^{0.26} {Pr}^{- 2 / 3}$$

where, “Cp” and “Pr” represent specific heat capacities of air at constant pressure, and the Prandtle number of air, respectively.

Accordingly, the heat discharge performance Q of the electronic chip-cooling heat sink according to the present invention can be expressed by the following equation:

Q=hA(T_{w}−Tₐ)

where, “A” represents the surface area of the heat sink, and “T_{w}” and “Tₐ” represent the surface temperature of the heat sink and the temperature of cooling air, respectively.

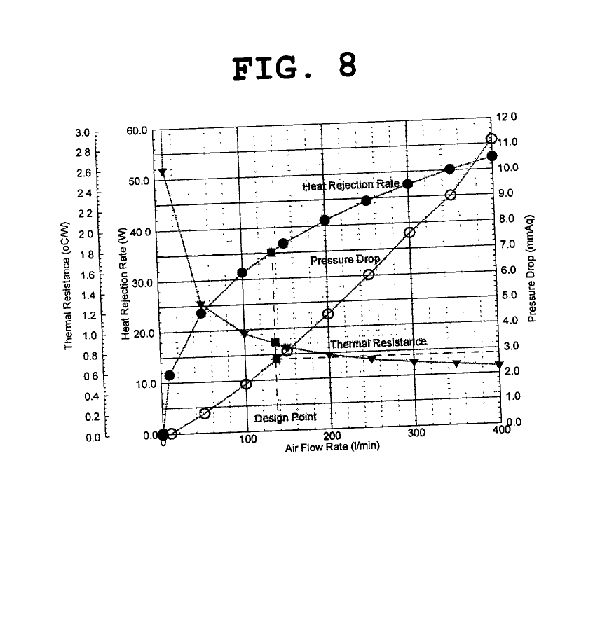

The performance characteristics of the above mentioned electronic chip-cooling heat sink may be depicted by the graph illustrated in FIG. 8.

The electronic chip-cooling heat sink proposed by the present invention has another feature in that a flow guide space having various shapes such as a semi-circular shape, a rectangular shape, and a triangular shape is defined between the inner bottom surface of the heat sink and the lower end of each louver fin member facing the inner bottom surface of the heat sink in order to allow the air flow generated from the fans to strike against the inner bottom surface of the heat sink after passing between adjacent corrugated louver fins, and then to flow horizontally along the inner bottom surface of the heat sink. By virtue of this configuration, it is possible to obtain a maximum heat transfer effect.

In order to further promote the heat transfer effect at the inner bottom surface of the heat sink, a plurality of fins having various shapes may be formed at the inner bottom surface of the heat sink to increase the heat transfer surface area of the heat sink.

The flow guide space has a hydraulic diameter of 2.0 to 15.0 mm capable of providing superior effects in terms of the convective heat transfer and air flow resistance.

The hydraulic diameter of the flow guide space is defined as follows:

Dₕ=4A_{c}/p

Dₕ: Hydraulic diameter;

A_{c}: Cross-sectional area of the space; and

P: Wetted perimeter

Now, the function of the electronic chip-cooling heat sink having the above mentioned configuration according to the present invention will be described.

When heat is generated from the electronic chip 6, which is a heat emitting body, it is rapidly transferred to the heat discharge fins 3 and corrugated louver fin members 10 via the body 2 of the heat sink 1.

The heat transferred in the above mentioned fashion is then partially discharged in accordance with the convection operation of the heat discharge fins 3 and corrugated louver fin members 10, and the air blowing operation of the fan motor 5.

In this case, a large part of the heat transferred to the heat discharge fins 3 is rapidly discharged by the corrugated louver fin members 10.

That is, the corrugated louver fin members 10 can rapidly discharge a large quantity of heat in accordance with its convection operation in that they a maximum heat discharge area because they are machined to have a wave shape, that is, a corrugated shape.

In particular, the louvers 11 formed at each corrugated louver fin member 10 serves to prevent the formation of a thermal boundary layer while not only forming a turbulent flow from air introduced in accordance with a natural convection or the air blowing operation of the fan motor 5, but also varying the direction of the air flow. As a result, it is possible to discharge a maximum quantity of heat transferred, in accordance with a forced convection.

Thus, the heat sink 1 provided with the corrugated louver fin members 10 as mentioned above can efficiently cool the electronic chip 6, thereby preventing the electronic chip 6 from being erroneously operated due to overheat.

In the electronic chip-cooling heat sink having the above mentioned configuration according to the present invention, there is an advantage in that a great improvement in heat discharge characteristics is obtained because the heat sink has a maximum heat conduction cross-sectional area and a maximum convective heat transfer area by virtue of the corrugated louver fin members each arranged adjacent heat discharge fins.

Such an improvement in heat discharge characteristics results in an increase in cooling efficiency. Accordingly, it is possible to reduce the volume and weight of the heat sink, thereby achieving a miniature and lightness of the heat sink. Moreover, there is an advantage in that it is possible to ensure heat discharge characteristics desired for future electronic chips configured to generate a large quantity of heat.

Although the preferred embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A heat sink for discharging an electronic chip, comprising:
a body contacting the surface of the electronic chip at one major surface thereof and received heat emitted from the surface of the electronic chip, the one major surface of the body being flat;
a plurality of heat discharge fins formed integrally with the body and adapted to discharge the heat, transferred to the body, to the atmosphere, the heat discharge fins being protruded from the other major surface of the body while being uniformed spaced from one another; and
a plurality of corrugated louver fin members each interposed between adjacent ones of the heat discharge fins and formed by repeatedly bending a thin plate member to have a wave shape, each of the corrugated louver fin members having a plurality of louvers adapted to create a turbulent flow of air while varying the direction of the air flow.

2. The heat sink according to claim 1, wherein each of the heat discharge fins has a thickness of 1.0 to 5.0 mm, and the body has a thickness of 2.0 to 10.0 mm.

3. The heat sink according to claim 1, wherein each of the corrugated louver fin members is arranged in parallel to the direction of the air flow and welded to associated ones of the heat discharge fins in accordance with a brazing method, to generate a minimum resistance of the air flow.

4. The heat sink according to claim 1, further comprising:
a flow guide space defined between the other major surface of the body and an end of an associated one of the corrugated louver fin members facing the other major surface of the body, the flow guide space having a shape selected from the group consisting of a semi-circular shape, a rectangular shape, and a triangular shape, and a hydraulic diameter of 2.0 to 15.0 mm; and
a plurality of fins having various protruded from a portion of the other major surface of the body defined within the flow guide space.

5. The heat sink according to claim 1, wherein each of the corrugated louver fin members is made of an aluminum material coated with a clad material.

6. The heat sink according to claim 1, further comprising:
a pair of hooks protruded from those of the heat discharge fins respectively arranged at opposite lateral edges of the body, each of the hooks having a desired height; and
a fan motor engaged with the hooks so that it is mounted to the body, the fan motor serving to forcibly blow air toward the heat discharge fins and the corrugated louver fin members.

7. The heat sink according to claim 1, wherein each of the corrugated louver fin members has a thickness of 0.1 to 0.5 mm, a shape bent in the form of corrugated fins having a pitch of 1.0 to 5.0 mm to obtain a maximum heat transfer area, and is provided with louvers formed by cutting each of the corrugated fins to form a plurality of uniformly spaced slits, and then bending portions of the corrugated louver fin defined by the slits, respectively, each of the louvers having an angle of 10 to 50°.

8. The heat sink according to claim 1, wherein the body, the heat discharge fins, and the corrugated louver fin members are made of aluminum or copper.
